(19) United States
(12) Patent Application Publication
(10) Pub. No.: US 2025/0361965 A1
(43) Pub. Date: Nov. 27, 2025

(54) MANIFOLD BLOCK, MANIFOLD AND COOLING SYSTEM

(71) Applicant: Fulian Precision Electronics (Tianjin) Co., LTD., Tianjin (CN)

(72) Inventors: CHANG-JU WU, New Taipei (TW); CHIH-MIN LIN, New Taipei (TW)

(21) Appl. No.: 18/935,947

(22) Filed: Nov. 4, 2024

(30) Foreign Application Priority Data
May 22, 2024 (CN) 202410636296.X

(51) Int. Cl. F16L 41/03; F28F 9/02

(52) U.S. Cl. CPC F16L 41/03; F28F 9/0253

(57) ABSTRACT

Embodiments of the present disclosure relate to a manifold block, a manifold, and a cooling system using the manifold. The manifold block includes a manifold body having a hollow space, at least one hose barb and at least one connecting structure. The hose barb is connected to the manifold body and communicates with the hollow space, and each hose barb is used to connect a pipe. Each connecting structure is used to connect the manifold block to another manifold block in a rotatable manner. The manifold includes a plurality of manifold blocks. The manifold can adjust direction of the hose barb according to the orientation of the pipe, thereby shortening the length of the pipes in the cooling system and simplifying the layout of the pipes.

### FIELD

The subject matter herein generally relates to servers, specifically manifold blocks, manifolds including a plurality of the manifold blocks, and a cooling system using the manifold.

### BACKGROUND

A server with liquid cooling is more efficient at heat transfer than air cooling. Manifolds (also called multi-branch pipes) are key components of the liquid cooling system. Different parts of the liquid cooling system require manifolds of different shapes, which greatly increases the development cycle and R&D costs of the manifolds. In addition, after one end of the coolant pipes in the liquid cooling system is connected to the manifold, the other end needs to be bent multiple times before it can be connected to the part that needs heat dissipation. In such a scenario, the total length of the coolant pipes is long, and the pipes arrangement is complicated.

Therefore, there is room for improvement in the art.

### BRIEF DESCRIPTION OF THE DRAWINGS

Implementations of the present disclosure will now be described, by way of embodiment, with reference to the attached figures.

FIG. 1 is a schematic structural diagram of a manifold according to a first embodiment of the present disclosure.

FIG. 2 is an exploded view of the manifold in FIG. 1.

FIG. 3 is a cross-sectional view along a view line III-III of FIG. 1.

FIG. 4 is a schematic structural diagram of a first manifold block in FIG. 1.

FIG. 5 is a schematic structural diagram of a second manifold block in FIG. 1.

FIG. 6 is a partial schematic structural view of the first manifold block and the second manifold block in FIG. 1, before connection.

FIG. 7 is a schematic structural diagram of a third manifold block in FIG. 1.

FIG. 8 is a schematic structural diagram of a manifold according to a second embodiment of the present disclosure.

FIG. 9 is a schematic structural diagram of a fourth manifold block in FIG. 8.

FIG. 10 is a cross-sectional view along a view line X-X of FIG. 9.

FIG. 11 is a schematic structural diagram of a manifold according to a third embodiment of the present disclosure.

FIG. 12 is a schematic structural diagram of a fifth manifold block in FIG. 11.

FIG. 13 is a cross-sectional view along a view line XII-XII of FIG. 12.

FIG. 14 is a schematic structural diagram of a manifold according to a fourth embodiment of the present disclosure.

FIG. 15 is an exploded view of the manifold in FIG. 14.

FIG. 16 is a schematic structural diagram of a cooling system according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein may be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

The term “comprising” when utilized, means “including, but not necessarily limited to”; it specifically indicates open-ended inclusion or membership in the so-described combination, group, series, and the like. The disclosure is illustrated by way of example and not by way of limitation in the figures of the accompanying drawings in which like references indicate similar elements. It should be noted that references to “an” or “one” embodiment in this disclosure are not necessarily to the same embodiment, and such references can mean “at least one”.

A cooling system of a server usually includes a water inlet chamber, a water outlet chamber, a plurality of pipes, and a manifold. The manifold is used to connect multiple pipes, the pipes and the water inlet chamber, or the pipes and the water outlet chamber. A cooling distribution unit (CDU) sends the cooling fluid through the water inlet chamber into the pipe of the server's water-cooling plate. The water-cooling plate and a central processing unit (CPU) are attached to each other, and then the heat generated on the CPU is transferred to the cooling fluid flowing inside the water-cooling plate, thereby helping the CPU to cool down, ensuring that the CPU works within a suitable temperature range and preventing the CPU from being damaged due to overheating. Some pipes in the cooling system need to go through multiple bends to connect to the CPU, resulting in a complicated distribution of multiple pipes in the cooling system.

The present disclosure provides a manifold. The manifold includes at least two manifold blocks that can rotate relative to each other. Each manifold block includes a manifold body, at least one hose barb connected to the manifold body, and at least one connecting structure connected to the manifold body. The manifold body has a hollow space. The hose barb communicates with the hollow space. The connecting structure is used to rotatably connect the manifold block to another manifold block. The manifold blocks are rotatably connected in sequence, and an orientation of any hose barb can be changed with a rotation angle between th manifold blocks. The hollow spaces of the manifold blocks with each other in sequence. When any manifold block is rotated relative to an adjacent manifold block, the orientation of the hose barbs on the rotated manifold block can be changed. The manifold of the present disclosure facilitates the use of various connection scenarios to solve the above problems.

The manifold of the present disclosure will be described in detail through specific examples below.

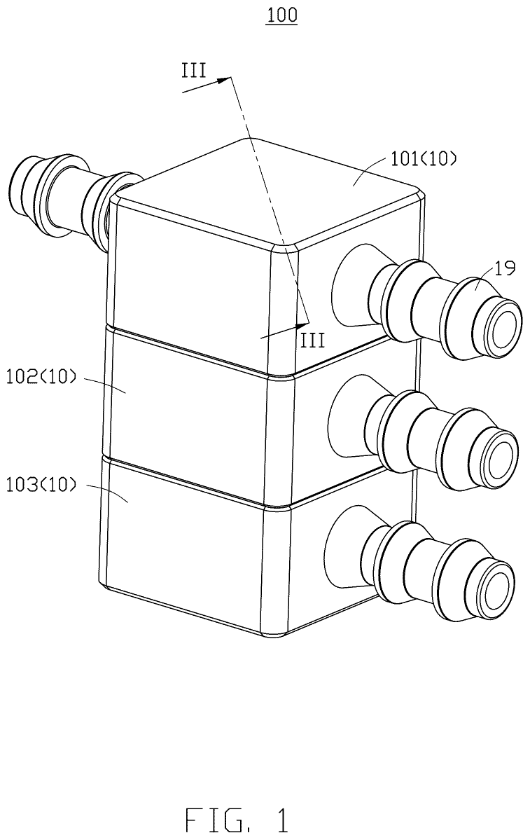

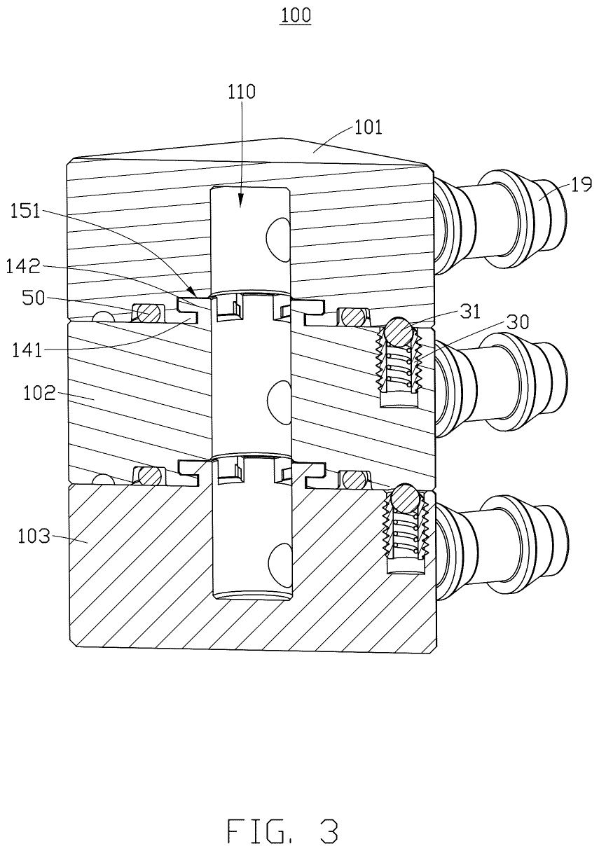

As shown in FIG. 1 and FIG. 3, a manifold 100 includes three manifold blocks 10. The three manifold blocks 10 are respectively a first manifold block 101, a second manifold block 102 and a third manifold block 103. The second manifold block 102 is between the first manifold block 101 and the third manifold block 103. The first manifold block 101, the second manifold block 102 and the third manifold block 103 connected in a mutually rotatable manner.

Each manifold block 10 includes a manifold body 11, at least one hose barb 19 connected to the manifold body 11, and at least one connecting structure 14 connected to the manifold body 11. The manifold body 11 has a hollow space 110. The hose barb 19 communicates with the hollow space 110. The hollow spaces 110 of the three manifold blocks 10 communicate with each other in sequence. Each connecting structure 14 is used to rotatably connect to another manifold block 10.

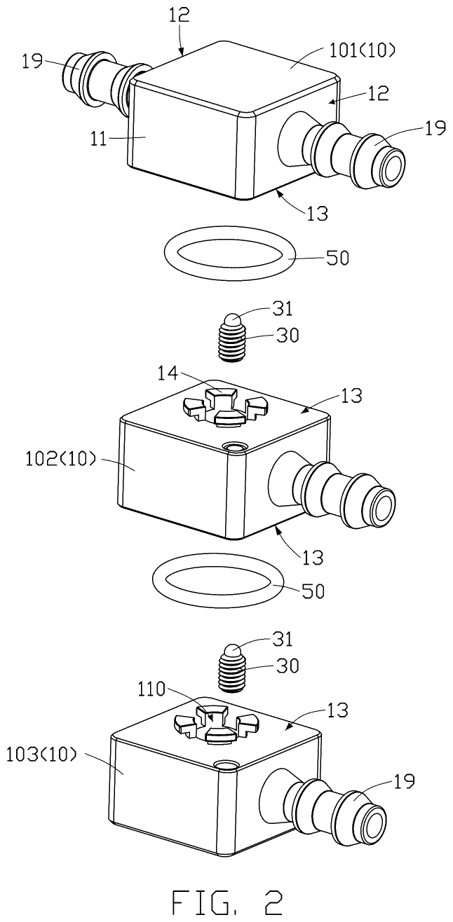

As shown in FIG. 2, the manifold body 11 of each manifold block 10 includes a plurality of surfaces facing different directions. The hose barb 19 and the connecting structure 14 are respectively formed on the surfaces facing different directions. Each hose barb 19 is a tubular structure with a hole, so that the hose barb 19 communicates with the hollow space 110 for drawing out fluid from the hollow space 110 or introducing fluid into the hollow space 110.

In one embodiment, the fluid is a liquid or a gas. The connecting structure 14 is to be rotatably connected to a corresponding connecting structure 14 in another manifold block 10. The manifold blocks 10 are connected in a rotatable manner in sequence, and an orientation of any one of the hose barbs 19 can be changed with a rotation angle between the manifold blocks 10.

As shown in FIG. 3, the connecting structure 14 is a first connecting structure 141 or a second connecting structure 142 matched with the first connecting structure 141. Among the two manifold blocks 10 connected to each other, the connecting structure of one manifold block 10 is the first connecting structure 141, and the connecting structure of the other manifold block 10 is the second connecting structure 142.

In addition, since the manifold block 10 at the end of the connecting chain of the manifold is connected to one other manifold block 10, so usually only one connecting structure (such as one first connecting structure 141 or one second connecting structure 142) is required; while the manifold block 10 in the middle of the connecting chain of the manifold needs to be connected to at least two other manifold blocks 10, so two connecting structures (such as two first connecting structures 141, or two second connecting structures 142, or one first connecting structure 141 and one second connecting structure 142) are usually required.

In one embodiment, the structures of the first manifold block 101, the second manifold block 102 and the third manifold block 103 are different from each other.

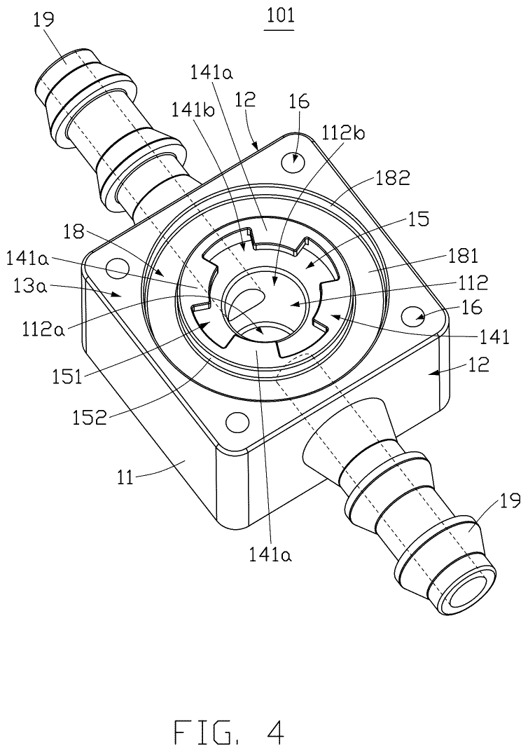

As shown in FIG. 4, the manifold body 11 is a rectangular block with the hollow space 112. The hose barbs 19 is formed on a first surface 12 of the manifold body 11, and the connecting structure 14 is formed on a second surface 13 of the manifold body 11. The manifold body 11 of the first manifold block 101 includes the first connecting structure 141. The manifold body 11 of the first manifold block 101 includes two first surfaces 12 and one second surface 13a. The two first surfaces 12 are approximately perpendicular to the second surface 13a. The two first sides 12 are respectively connected to one hose barb 19.

The connecting structure 14 of the first manifold block 101 is the first connecting structure 141, a first groove 15 is formed on the second surface 13a. The hollow space 112 of the first manifold block 101 is surrounded by a first bottom wall 112a and a first side wall 112b connected to the first bottom wall 112a. An opening is formed on the first side wall 112b to communicate with the hole of the hose barb 19.

The first groove 15 includes a second bottom wall 151 and a second side wall 152 connected to the second bottom wall 151. The hollow space 112 penetrates the second bottom wall 151, so that the hollow space 112 is in air communication with the second groove 15. The diameter of the circular opening formed on the second bottom wall 151 of the hollow space 112 is less than the diameter of the circular area surrounded by the second side wall 152. The second side wall 152 is connected to an end of the second bottom wall 151 away from the hollow space 112, and the second side wall 152 extends perpendicularly to the second bottom wall 151 in a direction away from the manifold body 11.

The first connecting structure 141 includes a plurality of spaced locking blocks 141a extending inward from the second side wall 152 of the first groove 15, and a spacing groove 141b is formed between any two adjacent locking blocks 141a. The extending direction of each locking block 141a is parallel to the second surface 13a, and each locking block 141 a is at an end of the second side wall 152 close to the notch of the first groove 15. A projection of the first connecting structure 141 on the second surface 13a is within a projection of the second bottom wall 151 on the second surface 13a.

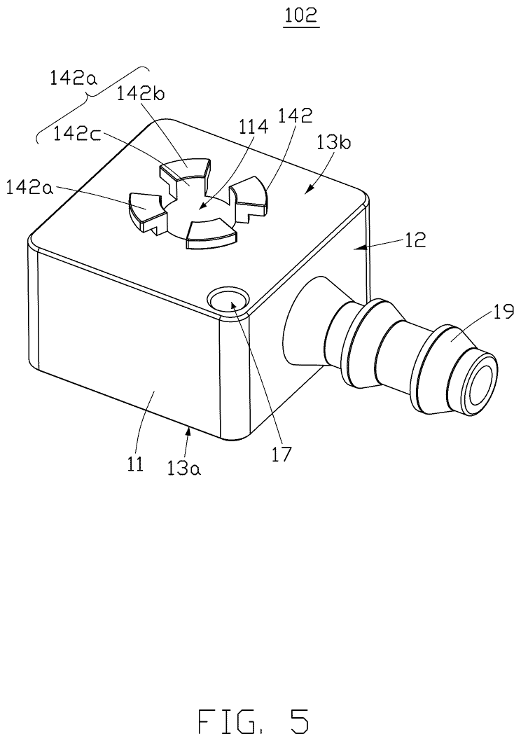

As shown in FIG. 3 and FIG. 5, the manifold body 11 of the second manifold block 102 includes one first connecting structure 141 and one second connecting structure 142. The first connecting structure 141 is used to connect the second manifold block 102 and the third manifold block 103, and the second connecting structure 142 is used to connect the second manifold block 102 and the first manifold block 101.

The manifold body 11 of the second manifold block 102 includes one first face 12 and two second faces 13a and 13b. The second surface 13a and the second surface 13b are opposite and parallel surfaces. The connecting structure formed on the second surface 13b is different from the connecting structure formed on the second surface 13a. The connecting structure formed on the second surface 13a is the first connecting structure 141. The connecting structure formed on the second surface 13b is the second connecting structure 142.

When the connecting structure 14 is the second connecting structure 142, the hollow space 114 penetrates the second surface 13b, and the hollow space 114 penetrates the second bottom wall 151 of the first groove 15. The hollow space 114 includes the first side wall 112a and does not include the first bottom wall 112b. The second connecting structure 142 includes a plurality of buckles 142a connected to the second surface 13b spaced from each other and distributed around the hollow space 114.

Each buckle 142a includes a connecting portion 142b connected to the second surface 13b, and a locking portion 142c formed by bending and extending an end of the connecting portion 142b away from the second surface 13b in a direction away from the opening of the hollow space 114. The connecting portion 142b extends perpendicularly to the second surface 13b in a direction away from the manifold body 11, and the locking portion 142c extends parallel to the second surface 13b in a direction away from the opening of the hollow space 114.

A number of buckles 142a of the second connecting structure 142 is the same as a number of locking blocks 141a of the first connecting structure 141. A projected outline of the second connecting structure 142 on the second surface 13b coincides with a projected outline of the first connecting structure 141 on the second surface 13b or is within the projected outline of the first connecting structure 141 on the second surface 13b.

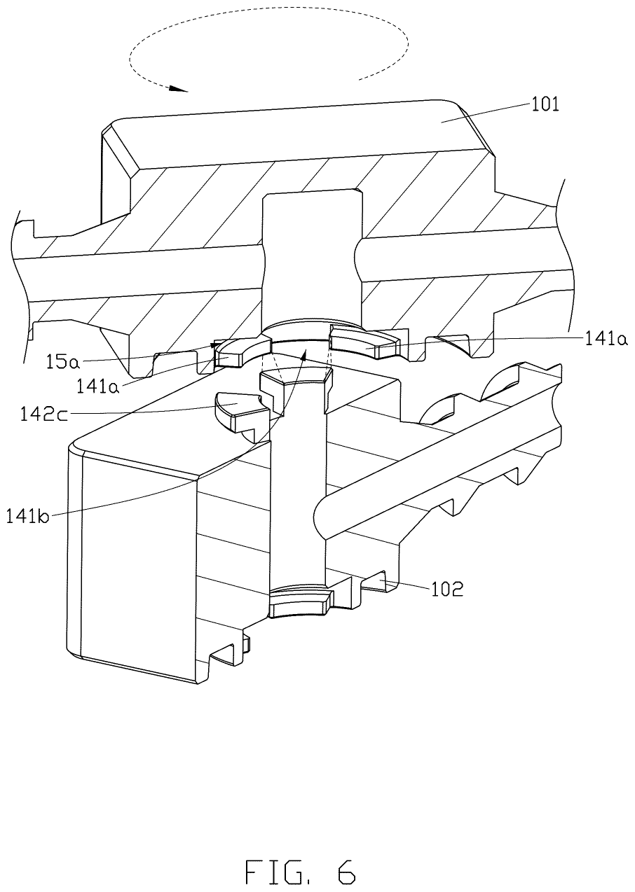

As shown in FIGS. 3 to 6, the connection mode between adjacent manifold blocks 10 will be described by taking the connection between the second surface 13a of the first manifold block 101 and the second surface 13b of the second manifold block 102 as an example. A clamping slot 15a is formed between the surface of the locking block 141a of the first connecting structure 141 close to the second bottom wall 151 and the second bottom wall 151. That is, the clamping slot 15a is surrounded by the second bottom wall 151, the second side wall 152 and the surface of the blocking block 141a close to the second bottom wall 151.

When the first manifold block 101 is connected with the second manifold block 102, each engaging portion 142c of the second connecting structure 142 passes through the spacing groove 141b between the two adjacent locking blocks 141a and enters the first groove 15, and each engaging portion 142c moves into the slot 15a along with the rotation of the second manifold block 102. That is, the engaging portion 142c of the second connecting structure 142 is rotatably located in the clamping slot 15a. When each engaging portion 142c is in a corresponding clamping slot 15a, the first manifold block 101 and the second manifold block 102 are fixed in a direction perpendicular to the surface where the manifold blocks 10 rotate relatively.

As shown in FIG. 2, FIG. 3 and FIG. 4, a plurality of second grooves 16, and a fourth groove 18 are formed on the second surface 13a. The fourth grooves 18 includes a fourth bottom wall 181 and a fourth side wall 182. The bottom wall 181 is on a side of the second side wall 152 away from the second bottom wall 151. The fourth bottom wall 181 surrounds and is connected to the second side wall 152, and the second grooves 16 are on a side of in the fourth groove 18 away from the first groove 15.

The manifold 100 further includes a sealing ring 50. The sealing ring 50 is clamped in the fourth groove 18 to seal two adjacent manifold blocks 10 (e. g., the first manifold block 101 and the second manifold block 102, or the second manifold block 102 and the second manifold block 102) and prevent the fluid in the hollow space 110 from flowing out from the gap between two adjacent manifold blocks 10.

A third groove 17 is formed on the second surface 13b. The position of the third groove 17 corresponds to the position of one second groove 16. The manifold 100 further includes a positioning screw 30 and a ball 31. Threads are formed on a side wall of the third groove 17, and the external threads of the positioning screw 30 is connected with the threads on the side wall of the third groove 17, so that the positioning screw 30 is threaded into the third groove 17.

The ball 31 is at an end of the positioning screw 30 away from the third groove 17. A part of the ball 31 is in the positioning screw 30, and the other part of the ball 31 is in the second groove 16, and the side wall of the second groove 16 is adapted to the shape of the ball 31. When the first manifold block 101 and the second manifold block 102 rotate relative to each other, the ball 31 switches from one second groove 16 to another second groove 16, so that the orientation of at least one hose barb 19 changes.

The process of the ball 31 switching from one second groove 16 to another second groove 16 is as follows: when the ball 31 leaves one second groove 16 and contacts the second surface 13a and is squeezed to move in a direction away from the second groove 16, the ball 31 slides relative to the second surface 13a with the relative rotation of the adjacent manifold block 10 and moves from the second surface 13a to another second groove 16, and finally gets stuck in the second groove 16.

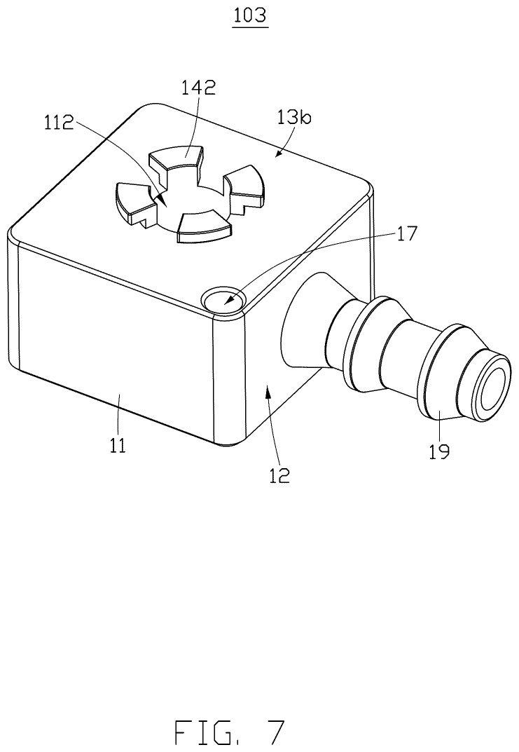

As shown in FIG. 7, the third manifold block 103 is substantially the same as the first manifold block 101. The third manifold block 103 is different from the first manifold block 101 in that the manifold body 11 of the third manifold block 103 includes one second connecting structure 142. The manifold body 11 of the third manifold block 103 includes one first surface 12 and one second surface 13b. The first surface 12 is substantially perpendicular to the second surface 13b. When the third manifold block 103 is rotatably connected with the second manifold block 102, the second connecting structure 142 of the third manifold block 103 is rotationally connected to the first connecting structure 141 of the second manifold block 102.

To sum up, the manifold 100 is composed of the plurality of manifold blocks 10, and each manifold block 10 includes at least one second surface 13 for rotating connection with adjacent manifold blocks 10. Among the two adjacent manifold blocks 10, the second surface 13a of one manifold block 10 is connected to the second surface 13b of the other manifold block 10, the first connecting structure 141 formed on the second surface 13a is correspondingly engaged with the second connecting structure 142 formed on the second surface 13b, and the second connecting structure 142 is rotatably in the first groove 16. The hose barb 19 is connected to the first surface 12 of the manifold block 10.

When the adjacent manifold blocks 10 rotate with each other, the orientation of the hose barb 19 changes with the rotation angle between adjacent manifold blocks 10, so that the manifold 100 is connected with multiple pipes at different orientations. Therefore, the manifold 100 in the present disclosure can adjust the direction of the hose barb 19 according to the orientation of the pipes in the cooling system using the manifold 100, so that the pipes can be connected to the manifold 100 and components requiring heat dissipation without multiple bends, thus shortening the length of the pipes and simplifying the layout of the pipes.

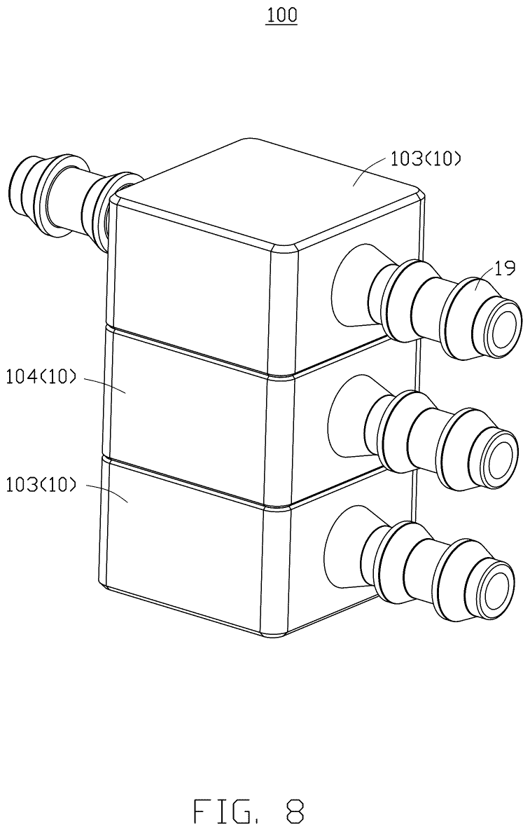

As shown in FIG. 8, the manifold 100 in the second embodiment includes two third manifold blocks 103 and one fourth manifold block 104 connected between the two third manifold blocks 103.

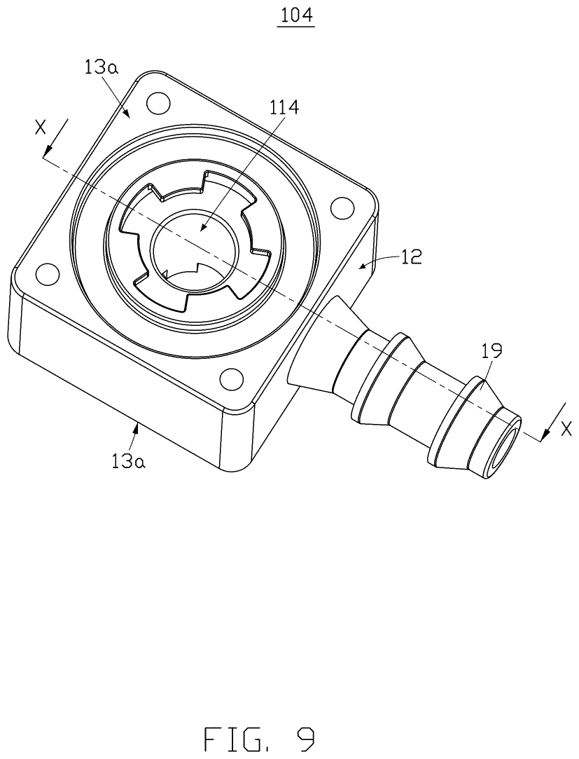

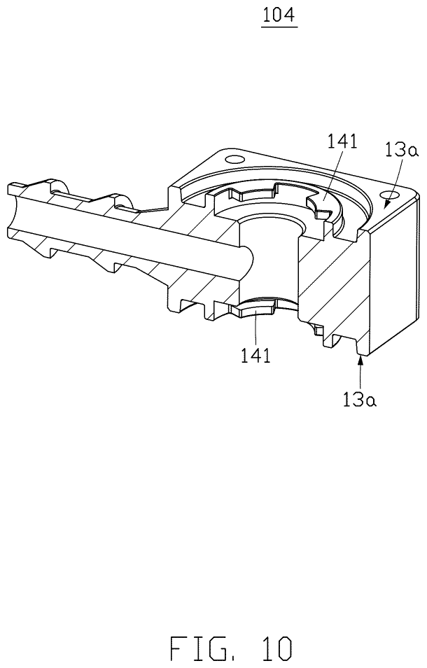

As shown in FIG. 9 and FIG. 10, the fourth manifold block 104 is substantially the same as the second manifold block 102. The fourth manifold block 104 is different from the second manifold block 102 is that the manifold body 11 of the fourth manifold block 104 includes two the first connecting structure 141. The manifold body 11 of the fourth manifold block 104 includes two second surfaces 13a, and the two second surfaces 13a are substantially parallel. When the fourth manifold block 104 is connected to the two third manifold blocks 103, the two first connecting structures 141 are respectively connected to the second connecting structures 142 of the two third manifold blocks 103.

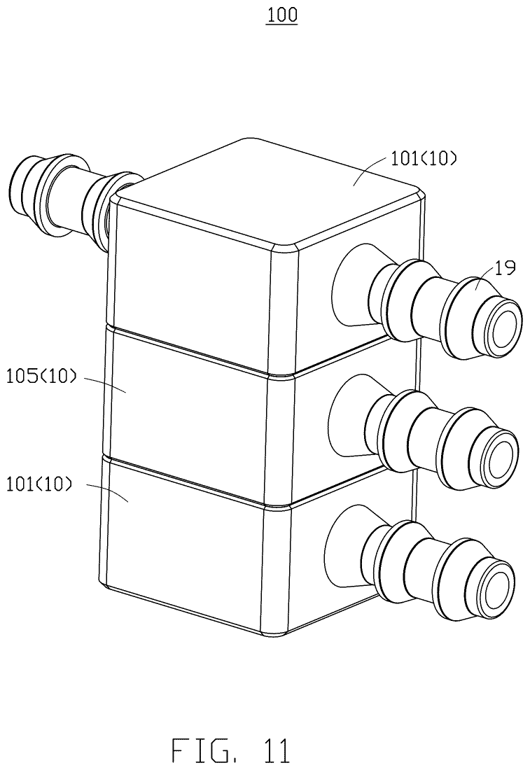

As shown in FIG. 11, the manifold 100 in the third embodiment includes two first manifold blocks 101 and one fifth manifold block 105 connected between the two first manifold blocks 101.

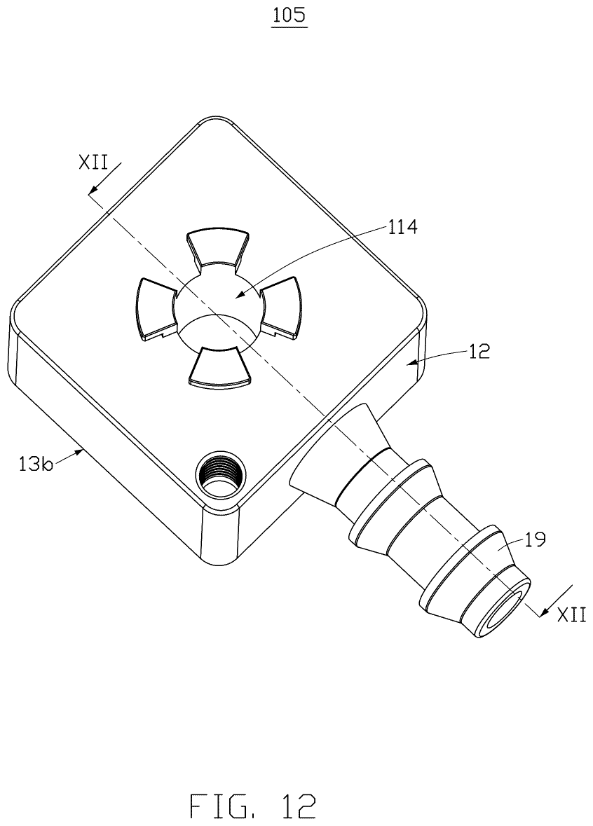

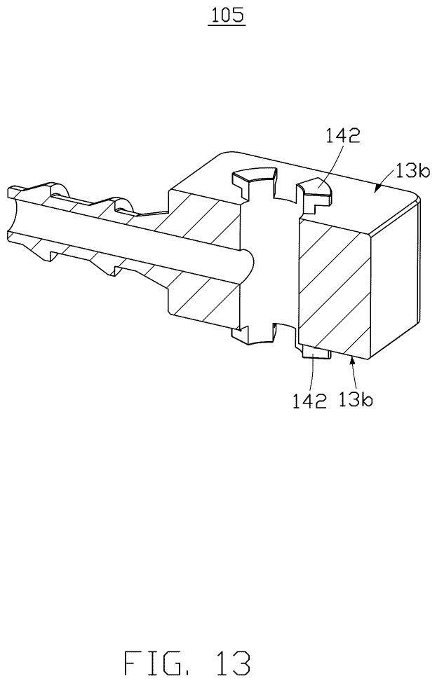

As shown in FIG. 12 and FIG. 13, the fifth manifold block 105 is substantially the same as the second manifold block 102. The fifth manifold block 105 is different from the second manifold block 102 is that the manifold body 11 of the fifth manifold block 105 includes two the second connecting structure 142. The manifold body 11 of the fifth manifold block 105 includes two second surfaces 13b, and the two second surfaces 13b are substantially parallel. When the fifth manifold block 105 is connected to the two first manifold blocks 101, the two second connecting structures 142 are connected to the first connecting structures 141 of the two first manifold blocks 101 respectively.

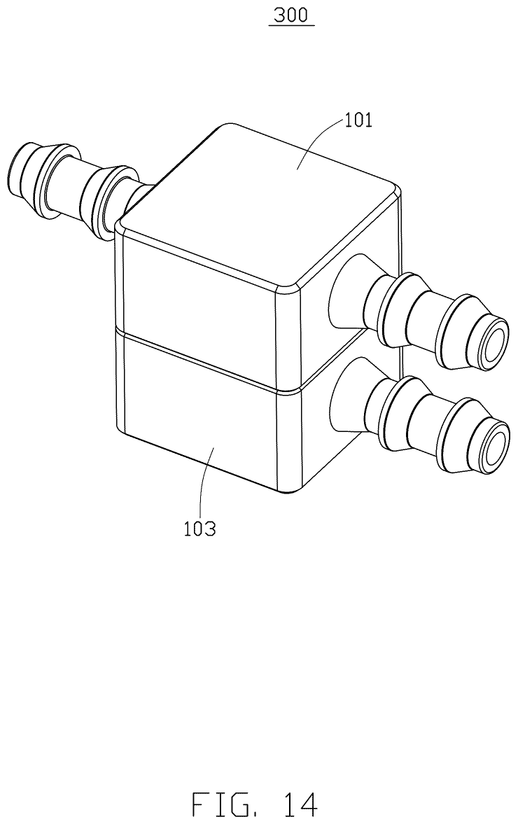

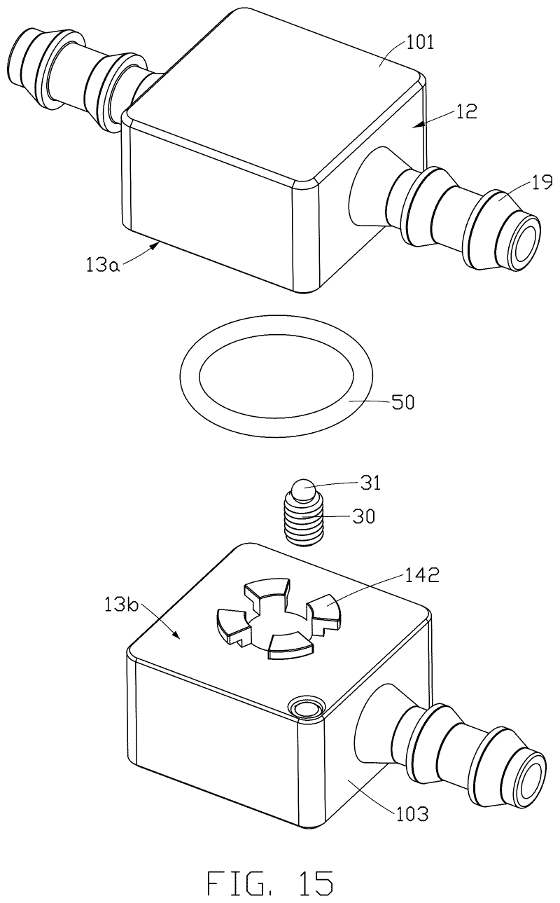

As shown in FIGS. 14 and 15, the manifold 300 in the fourth embodiment is substantially the same as the manifold 100 of the first embodiment. The manifold 300 in the fourth embodiment is different from the manifold 100 of the first embodiment is that the manifold 300 includes two manifold blocks 10, namely the first manifold block 101 and the third manifold block 103. The second surface 13a of the first manifold block 101 is connected to the second surface 13b of the third manifold block 103, so that the second connecting structure 142 is rotatably engaged in the first groove 15. When the first manifold block 101 and the third manifold block 103 rotate relative to each other, the orientation of the hose barb 19 changes, so that the manifold 300 adjusts the orientation of the hose barb 19 according to the orientation of the pipe.

The manifolds in the second through fourth embodiments can achieve all the beneficial effects of the first embodiment, which will not be repeated.

In other embodiments, the number of manifold blocks 10 can be more than three, such as four, five, six, etc. The number of the manifold block 10 and the number of the hose barb 19 can be set correspondingly according to the number of pipes that the manifold 100 needs to communicate with.

An embodiment of the present disclosure further provides a cooling system using the manifold.

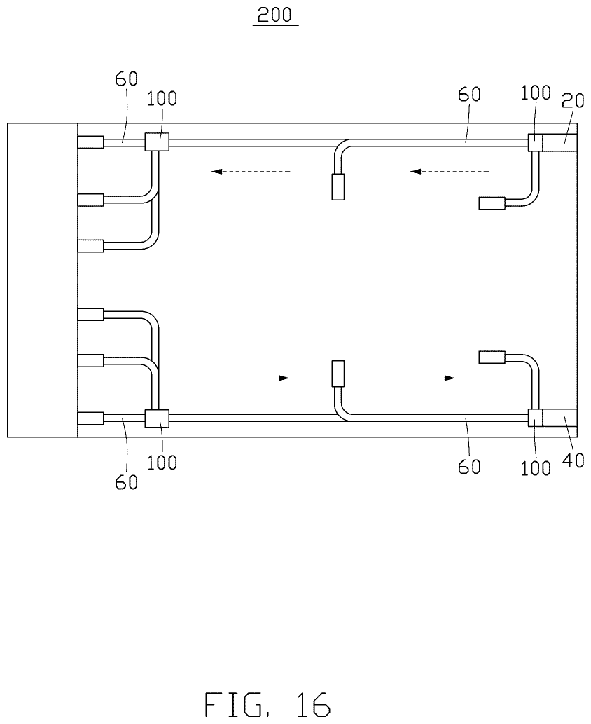

As shown in FIG. 16, a cooling system 200 includes a water inlet chamber 20, a water outlet chamber 40, a plurality of pipes 60, and at least one manifold as described in any of the above embodiments (including manifold 100 and manifold 300, etc., and the manifold 100 is used as an example below).

The manifold 100 is used to connect one of the pipes 60 to another pipe 60, or connect one of the pipes 60 to the water inlet chamber 20, or connect one of the pipes 60 to the water outlet chamber 40, thereby forming a flow path between the water inlet chamber 20, the water outlet chamber 40 and the pipes 60 to dissipate heat.

The water inlet chamber 20 is connected to the hose barb 19 of the manifold 100, so that the fluid flows from the water inlet chamber 20 through the hose barb 19 into the manifold 100. One end of the pipe 60 is connected to the hose barb 19, and the fluid in the manifold 100 flows into the pipe 60 through the hose barb 19, and the other end of the pipe 60 is connected to the pipe of the water-cooling plate in the CPU, and the CPU is helped to cool down by transferring heat to the fluid flowing in the pipe 60.

After the fluid flows through the CPU or other systems that need to be cooled, the temperature of the fluid rises, and the pipe 60 communicates with the water outlet chamber 40 through the manifold 100. The fluid with the increased temperature flows through pipe 60, the manifold 100 and the water outlet chamber 40 in turn, and finally flows out of the cooling system 200 from the water outlet chamber 40.

The cooling system 200 of the present disclosure reduces the temperature of the CPU by heat transfer, thereby ensuring that the CPU works within a suitable temperature range and preventing the CPU from being damaged due to overheating.

Since the manifold blocks 10 in the manifold 100 are connected in a rotatable manner, the orientation of the hose barb 19 of the manifold block 10 can be adjusted according to the different layouts of the water inlet chamber 20, the water outlet chamber 40 and the pipes 60, which is beneficial to simplifying the overall layout of the cooling system 200 and shortening the total length of the cooling pipes.

It is to be understood, even though information and advantages of the present exemplary embodiments have been set forth in the foregoing description, together with details of the structures and functions of the present exemplary embodiments, the disclosure is illustrative only. Changes may be made in detail, especially in matters of shape, size, and arrangement of parts within the principles of the present exemplary embodiments to the full extent indicated by the plain meaning of the terms in which the appended claims are expressed.

What is claimed is:

1. A manifold block comprising:
a manifold body having a hollow space;
at least one hose barb connected to the manifold body and communicating with the hollow space, the at least one hose barb configured to connect to a pipe; and
at least one connecting structure connected to the manifold body and configured to rotatably connect to the manifold block to another manifold block.

2. The manifold block according to claim 1, wherein the at least one hose barb and the at least one connecting structure are respectively formed on surfaces of the manifold body facing different directions, and the at least one connecting structure is configurated to be rotatably connected to a corresponding connecting structure of the other manifold block.

3. The manifold block according to claim 2, wherein any one of the at least one connecting structure is a first connecting structure or a second connecting structure matched with the first connecting structure, the at least one hose barb is formed on a first surface of the manifold body, and the at least one connecting structure is formed on a second surface of the manifold body, wherein
when the at least one connecting structure is the first connecting structure, a first groove is on the second surface, the hollow space penetrates through a bottom wall of the first groove, the first connecting structure comprises a plurality of spaced locking blocks extending inward from a side wall of the first groove, and a spacing groove is formed between any two adjacent locking blocks of the plurality of locking blocks; and
when the at least one connecting structure is the second connecting structure, the hollow space penetrates through the second surface, the second connecting structure comprises a plurality of buckles connected to the second surface, the plurality of buckles is spaced from each other and distributed around an opening of the hollow space, each of the plurality of buckles comprises a connecting portion connected to the second surface, and a locking portion which is formed by bending and extending an end of the connecting portion away from the second surface to a direction away from the opening of the hollow space.

4. The manifold block according to claim 3, wherein at least one of the at least one connecting structure is a first connecting structure.

5. The manifold block according to claim 3, wherein at least one of the at least one connecting structure is a second connecting structure.

6. The manifold block according to claim 3, wherein the at least one connecting structure comprises at least two connecting structures comprising one first connecting structure and one second connecting structure, the manifold body has two different second surfaces, and the first connecting structure and the second connecting structure are formed on the two different second surfaces of the manifold body.

7. The manifold block according to claim 3, wherein the at least one connecting structure comprises at least two connecting structures comprising two first connecting structures, the manifold body has two different second surfaces, and the two first connecting structures are formed on the two different second surfaces of the manifold body.

8. The manifold block according to claim 3, wherein the at least one connecting structure comprises at least two connecting structures comprising two second connecting structures, the manifold body has two different second surfaces, and the two second connecting structures are formed on the two different second surfaces of the manifold body.

9. A manifold comprising at least two manifold blocks, each of the at least two manifold blocks comprising:
a manifold body having a hollow space;
at least one hose barb connected to the manifold body and communicating with the hollow space, the at least one hose barb configurated to connect to a pipe; and
at least one connecting structure connected to the manifold body and configurated to rotatably connect to the manifold block to another manifold block;
wherein the at least two manifold blocks are rotatably connected in sequence, an orientation of any one of the at least one hose barb can be changed with a rotation angle between the at least two manifold blocks, and the hollow spaces of the at least two manifold blocks communicate with each other in sequence.

10. The manifold according to claim 9, wherein the at least one hose barb and the at least one connecting structure are respectively formed on surfaces of the manifold body facing different directions, and the at least one connecting structure is configurated to be rotatably connected to a corresponding connecting structure of the other manifold block.

11. The manifold according to claim 10, wherein any one of the at least one connecting structure is a first connecting structure or a second connecting structure matched with the first connecting structure, the at least one hose barb is formed on a first surface of the manifold body, and the at least one connecting structure is formed on a second surface of the manifold body, wherein
when the at least one connecting structure is the first connecting structure, a first groove is on the second surface, the hollow space penetrates through a bottom wall of the first groove, the first connecting structure comprises a plurality of spaced locking blocks extending inward from a side wall of the first groove, and a spacing groove is formed between any two adjacent locking blocks of the plurality of locking blocks; and
when the at least one connecting structure is the second connecting structure, the hollow space penetrates through the second surface, the second connecting structure comprises a plurality of buckles connected to the second surface, the plurality of buckles is spaced from each other and distributed around an opening of the hollow space, each of the plurality of buckles comprises a connecting portion connected to the second surface, and a locking portion which is formed by bending and extending an end of the connecting portion away from the second surface to a direction away from the opening of the hollow space.

12. The manifold according to claim 11, wherein at least one of the at least one connecting structure is a first connecting structure; or at least one of the at least one connecting structure a second connecting structure; or the at least one connecting structure comprises at least two connecting structures comprising one first connecting structure and one second connecting structure, the manifold body has two different second surfaces, and the first connecting structure and the second connecting structure are formed on the two different second surfaces of the manifold body; or the at least one connecting structure comprises at least two connecting structures comprising two first connecting structures, the manifold body has two different second surfaces, and the two first connecting structures are formed on the two different second surfaces; or the at least one connecting structure comprises at least two connecting structures comprising two second connecting structures, the manifold body has two different second surfaces, and the two second connecting structures are formed on the two different second surfaces of the manifold body.

13. The manifold according to claim 12, further comprising a positioning screw and a ball, wherein a plurality of second grooves is formed on the second surface provided with the first connecting structure, and a third groove is formed on the second surface provided with the second connecting structure; the positioning screw is threaded into the third groove, the ball is at an end of the positioning screw away from the third groove, a part of the ball is in the positioning screw, and another part of the ball is in the second groove; and when the at least two manifold blocks rotate relative to each other, the ball switches from one of the plurality of second grooves to another, so that the orientation of the at least one hose barb changes.

14. The manifold according to claim 13, further comprising a sealing ring, wherein a fourth groove is formed on the second surface with the first connecting structure, and the sealing ring is clamped in the fourth groove to seal two adjacent manifold blocks of the at least two manifold blocks.

15. A cooling system comprising:
a water inlet chamber;
a water outlet chamber;
a plurality of pipes; and
at least one manifold, each of the at least one manifold configured to connect one pipe of the plurality of pipes to another pipe of the plurality of pipes, or connect one pipe of the plurality of pipes to the water inlet chamber, or connect one pipe of the plurality of pipes to the water outlet chamber, thereby forming a flow path between the water inlet chamber, the water outlet chamber and the plurality of pipes to dissipate heat;
wherein each of the at least one manifold comprises at least two manifold blocks, and each of the at least two manifold blocks comprises:
a manifold body having a hollow space;
at least one hose barb connected to the manifold body and communicating with the hollow space, the at least one hose barb configurated to connect to a pipe; and
at least one connecting structure connected to the manifold body and configurated to rotatably connect to the manifold block to another manifold block;
wherein the at least two manifold blocks are rotatably connected in sequence, an orientation of any one of the at least one hose barb can be changed with a rotation angle between the at least two manifold blocks, and the hollow spaces of the at least two manifold blocks communicate with each other in sequence.

16. The cooling system according to claim 15, wherein the at least one hose barb and the at least one connecting structure are respectively formed on surfaces of the manifold body facing different directions, and the at least one connecting structure is configurated to be rotatably connected to a corresponding connecting structure in another manifold block.

17. The cooling system according to claim 16, wherein any one of the at least one connecting structure is a first connecting structure or a second connecting structure matched with the first connecting structure, the at least one hose barb is formed on a first surface of the manifold body, and the at least one connecting structure is formed on a second surface of the manifold body, wherein
when the at least one connecting structure is the first connecting structure, a first groove is on the second surface, the hollow space penetrates through a bottom wall of the first groove, the first connecting structure comprises a plurality of spaced locking blocks extending inward from a side wall of the first groove, and a spacing groove is formed between any two adjacent locking blocks of the plurality of locking blocks; and
when the at least one connecting structure is the second connecting structure, the hollow space penetrates through the second surface, the second connecting structure comprises a plurality of buckles connected to the second surface, the plurality of buckles is spaced from each other and distributed around an opening of the hollow space, each of the plurality of buckles comprises a connecting portion connected to the second surface, and a locking portion which is formed by bending and extending an end of the connecting portion away from the second surface to a direction away from the opening of the hollow space.

18. The cooling system according to claim 17, wherein at least one of the at least one connecting structure is a first connecting structure; or at least one of the at least one connecting structure is a second connecting structure; or the at least one connecting structure comprises at least two connecting structures comprising one first connecting structure and one second connecting structure, the manifold body has two different second surfaces and the first connecting structure and the second connecting structure are formed on the two different second surfaces of the manifold body; or the at least one connecting structure comprises at least two connecting structures comprising two first connecting structures, the manifold body has two different second surfaces, and the two first connecting structures are formed on the two different second surfaces of the manifold body; or the at least one connecting structure comprises at least two connecting structures comprising two second connecting structures, the manifold body has two different second surfaces, and the two second connecting structures are formed on the two different second surfaces of the manifold body.

19. The cooling system according to claim 18, wherein the manifold further comprises a positioning screw and a ball; a plurality of second grooves is formed on the second surface provided with the first connecting structure, and a third groove is formed on the second surface provided with the second connecting structure; the positioning screw is threaded into the third groove, the ball is at an end of the positioning screw away from the third groove, a part of the ball is in the positioning screw, and another part of the ball is in the second groove; and when the at least two manifold blocks rotate relative to each other, the ball switches from one of the plurality of second grooves to another, so that the orientation of the at least one hose barb changes.

20. The cooling system according to claim 19, wherein the manifold further comprises a sealing ring, a fourth groove is formed on the second surface with the first connecting structure, and the sealing ring is clamped in the fourth groove to seal two adjacent manifold blocks of the at least two manifold blocks.
